(19) United States
(12) Patent Application Publication
(10) Pub. No.: US 2008/0252490 A1
(43) Pub. Date: Oct. 16, 2008

(54) Merging A Codec With A Digital Media File and Playing A Digital Media File On A Playback Device

(76) Inventors: David R. Chiluk, Austin, TX (US); Logan S. Gabriel, Raleigh, NC (US); Eric R. Kern, Chapel Hill, NC (US); Michael S. Rollins, Durham, NC (US); Paul K. Scrutton, Durham, NC (US); Janae V. Simons, Durham, NC (US); Torez Smith, Austin, TX (US); David R. Woodham, Cedar Park, TX (US); Tong Yu, Cary, NC (US)

Correspondence Address: IBM (RPS-BLF);c/o BIGGERS & OHANIAN, LLP, P.O. BOX 1469, AUSTIN, TX, 78767-1469, US

(21) Appl. No.: 11/733,461

(22) Filed: Apr. 10, 2007

(51) Int. Cl. H04L 1/00; H03M 1/22

(52) U.S. Cl. 341/3

(57) ABSTRACT

Merging a codec with a digital media file, including receiving, by a digital media provider from a playback device through a data communications network, a request for the digital media file, the digital media file comprising digital media content encoded by a codec, identifying, by the digital media provider, the codec by which the digital media content was encoded, inserting, by the digital media provider, the codec into the digital media file, distributing the digital media file with the inserted codec to the playback device through the data communications network. Playing a digital media file on a playback device, including receiving the digital media file in the playback device, extracting the codec from within the digital media file, installing, by the playback device, the codec for operation on the playback device, and decoding, by the playback device through the codec, the digital media content for playback on the playback device.

### BACKGROUND OF THE INVENTION

1. Field of the Invention

The field of the invention is data processing, or, more specifically, methods, apparatus, and products for merging a codec with a digital media file and playing a digital media file on a playback device.

2. Description of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. As advances in semiconductor processing and computer architecture push the performance of the computer higher and higher, more sophisticated computer software has evolved to take advantage of the higher performance of the hardware, resulting in computer systems today that are much more powerful than just a few years ago.

One of the areas in which progress has been made is in distribution of digital media. Large volumes of digital media are distributed today from digital media providers. Downloading digital media, such as video files, for example, and playing them on a computer today, however, is not very user friendly. A downloaded movie, for example, Since the movie file contains compressed video and audio data, a third party codec is often required to decode and view the video file. Currently, the needed codec is not connected to the downloaded movie file, so users have to search the web for them. These codecs are sometimes tough to find and other times not available. Some applications like Windows Media Player™ will try to retrieve the codec. Even Windows Media Player cannot always identify the codec needed or cannot find the appropriate codec.

### SUMMARY OF THE INVENTION

Methods and apparatus for merging a codec with a digital media file, including receiving, by a digital media provider from a playback device through a data communications network, a request for the digital media file, the digital media file comprising digital media content encoded by a codec; identifying, by the digital media provider, the codec by which the digital media content was encoded; inserting, by the digital media provider, the codec into the digital media file; distributing the digital media file with the inserted codec to the playback device through the data communications network. Methods and apparatus for playing a digital media file on a playback device, including receiving the digital media file in the playback device; extracting, by the playback device, the codec from within the digital media file; installing, by the playback device, the codec for operation on the playback device; and decoding, by the playback device through the codec, the digital media content for playback on the playback device.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a network diagram illustrating an exemplary system for merging a codec with a digital media file and playing a digital media file on a playback device according to embodiments of the present invention.

FIG. 2 sets forth a block diagram of automated computing machinery comprising an example of a computer useful as a digital media provider in merging a codec with a digital media file according to embodiments of the present invention.

FIG. 3 sets forth a block diagram of automated computing machinery comprising an example of a computer useful as a playback device in playing digital media files according to embodiments of the present invention.

FIG. 4 sets forth a flow chart illustrating an exemplary method for merging a codec with a digital media file according to embodiments of the present invention.

FIG. 5 sets forth a flow chart illustrating a further exemplary method for merging a codec with a digital media file according to embodiments of the present invention.

FIG. 6 sets forth a flow chart illustrating an exemplary method for playing a digital media file on a playback device according to embodiments of the present invention.

FIG. 7 sets forth a flow chart illustrating a further exemplary method for playing a digital media file on a playback device according to embodiments of the present invention.

FIG. 8 sets forth a flow chart illustrating a further exemplary method for playing a digital media file on a playback device according to embodiments of the present invention.

FIG. 9 sets forth a flow chart illustrating a further exemplary method for playing a digital media file on a playback device according to embodiments of the present invention.

FIGS. 10A and 10B set forth block diagrams illustrating examples of digital media files for use in merging a codec with a digital media file and playing a digital media file on a playback device according to embodiments of the present invention.

### DETAILED DESCRIPTION OF EXEMPLARY EMBODIMENTS

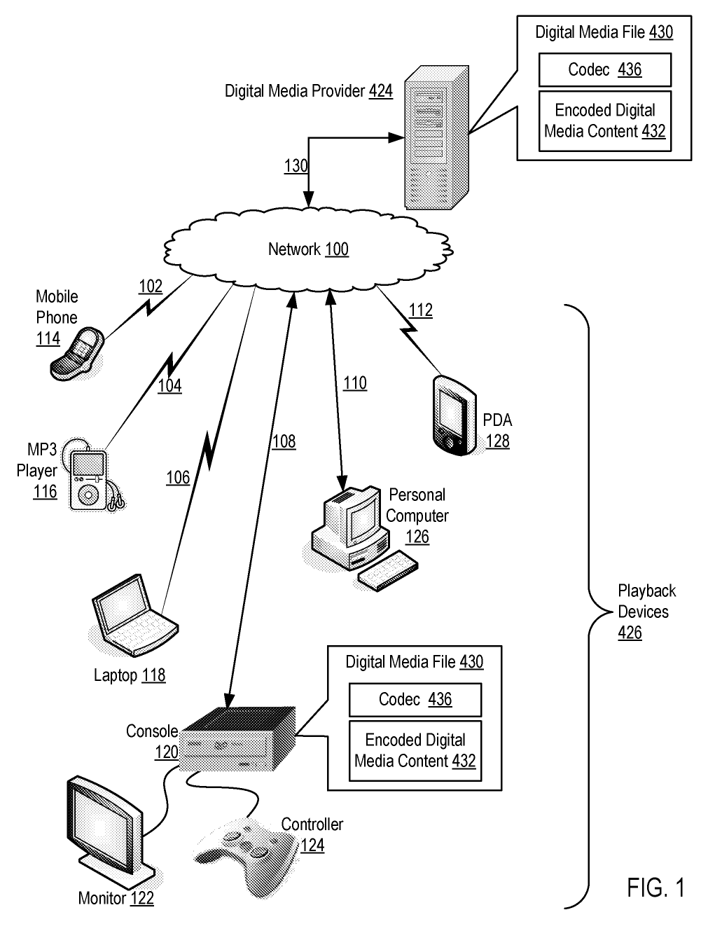

Exemplary methods, systems, and products for merging a codec with a digital media file and playing a digital media file on a playback device according to embodiments of the present invention are described with reference to the accompanying drawings, beginning with FIG. 1. FIG. 1 sets forth a network diagram illustrating an exemplary system for merging a codec with a digital media file and playing a digital media file on a playback device according to embodiments of the present invention. The system of FIG. 1 operates generally to merge a codec with a digital media file according to embodiments of the present invention by receiving, by a digital media provider (424) from a playback device (426) through a data communications network (100), a request for the digital media file (430). The digital media file (430) includes digital media content (432) encoded by a codec (436). The digital media provider identifies the codec (436) by which the digital media content (432) was encoded, inserts the codec (436) into the digital media file (430), and distributes (408) the digital media file (430) with the inserted codec (436) to a playback device (426) through the data communications network (100). The system of FIG. 1 operates generally to play a digital media file on a playback device according to embodiments of the present invention by receiving (502) the digital media file (430) in a playback device (426). The playback device (426) extracts the codec (436) from within the digital media file (430), installs the codec (436) for operation on the playback device (426), and decodes through the codec (436) the digital media content (512) for playback on the playback device (426).

A ‘codec’ (436), as the term is used in this specification, is a ‘COder/DECoder,’ a module of computer program instructions capable of performing encoding and decoding of digital media content, that is, upon digital data in the form of a digital signal, digital file (430), or a stream of digital data. Codecs encode a file or a stream for transmission, storage, or encryption and decode it for playback, viewing or editing. Codecs are often used in videoconferencing and streaming media applications. A video camera's analog-to-digital (‘ADC’) converts its analog signals into digital signals, which are then passed through a codec for digital transmission or storage. A playback device then runs the signal through a codec and a digital-to-analog (‘DAC’) for playback on an analog display. The raw encoded form of audio and video data is sometimes called ‘essence,’ or in this specification, ‘encoded digital media content’ (432), to distinguish it from the metadata information that goes with the encoded digital media content to make up the information content of a file or stream and any “wrapper” data that is then added to aid access to or improve the robustness of the file or stream.

Many multimedia data streams need to contain both audio and video data, and often some form of metadata that permits synchronization of the audio and video. Each of these three streams may be handled by different programs, processes, or hardware; but for a multimedia data stream or file to be useful in stored or transmitted form, the audio and video data are encapsulated together in a container format, a digital media content file or stream format. Audio Video Interleave (‘AVI’), sometimes referred to as a codec, is in fact a container format, which many codecs might use. There are other well known alternative containers such as Ogg, ASF, QuickTime, RealMedia, Matroska, and MP4. Examples of codecs useful for merging a codec with a digital media file and playing a digital media file on a playback device according to embodiments of the present invention include:
H.261
H.263
MPEG-4 ASP (Advanced Simple Profile) or MPEG-4 Part 2
H.263v2
H.264, also known as MPEG-4 AVC (Advanced Video Coding) or MPEG-4 Part 10
KVCD
MJPEG
MPEG-1 Video
MPEG-2 Video
MPEG-4 ASP (Advanced Simple Profile)
MPEG-4 AVC (Advanced Video Coding)
Pixlet
RealVideo
Snow Wavelet Codec
Tarkin
Theora
VC-1 (the primary video codec used by HD DVD and Blu-ray)
Windows Media Video
And others—as may occur to those of skill in the art

A ‘digital media provider’ (430), as the term is used in this specification, is automated computing machinery, one or more computers, that provides the service of distributing or downloading on request digital media files from the provider to a playback device. In the example of FIG. 1, the digital media provider (424) is represented as a web server coupled to the network (100) through wireline connection (130). Many forms of computer can serve as a digital media provider, however, including, for example, personal computers, web servers, mainframe computers, and so on.

A ‘playback device’ (426) is any automated computing machinery capable of playing a digital media file in accordance with embodiments of the present invention. The system of FIG. 1 includes several example playback devices (426):
mobile telephone (114), which is coupled for data communications to data communications network (100) through wireless connection (102),
MP3 player (116), which is coupled for data communications to data communications network (100) through wireless connection (104),
laptop computer (118), which is coupled for data communications to data communications network (100) through wireless connection (106),
Video game console (120), which is coupled for data communications to data communications network (100) through wireline connection (108), and together with video monitor (122) and video game controller (124), makes up a video game system,
personal computer (126), which is coupled for data communications to data communications network (100) through wireline connection (110), and
personal digital assistant (‘PDA’) (128), which is coupled for data communications to data communications network (100) through wireless connection (112).

A ‘digital media file’ (430), as the term is used in this specification, is an aggregation of digital media data cognizable as a file by a computer operating system. Digital media files are ‘played’ or ‘played back’ by a playback device. A digital media file can be implemented in a wide variety of file formats, including, for example, audio files, video files, graphics files such as JPEG files, web pages such as HTML files or XML files, computer-aided design (‘CAD’) files, video game files, and so on.

The arrangement of the digital media provider (424) and other devices making up the exemplary system illustrated in FIG. 1 are for explanation, not for limitation. Data processing systems useful according to various embodiments of the present invention may include additional servers, routers, other devices, and peer-to-peer architectures, not shown in FIG. 1, as will occur to those of skill in the art. Networks in such data processing systems may support many data communications protocols, including for example TCP (Transmission Control Protocol), IP (Internet Protocol), HTTP (HyperText Transfer Protocol), WAP (Wireless Access Protocol), HDTP (Handheld Device Transport Protocol), and others as will occur to those of skill in the art. Various embodiments of the present invention may be implemented on a variety of hardware platforms in addition to those illustrated in FIG. 1.

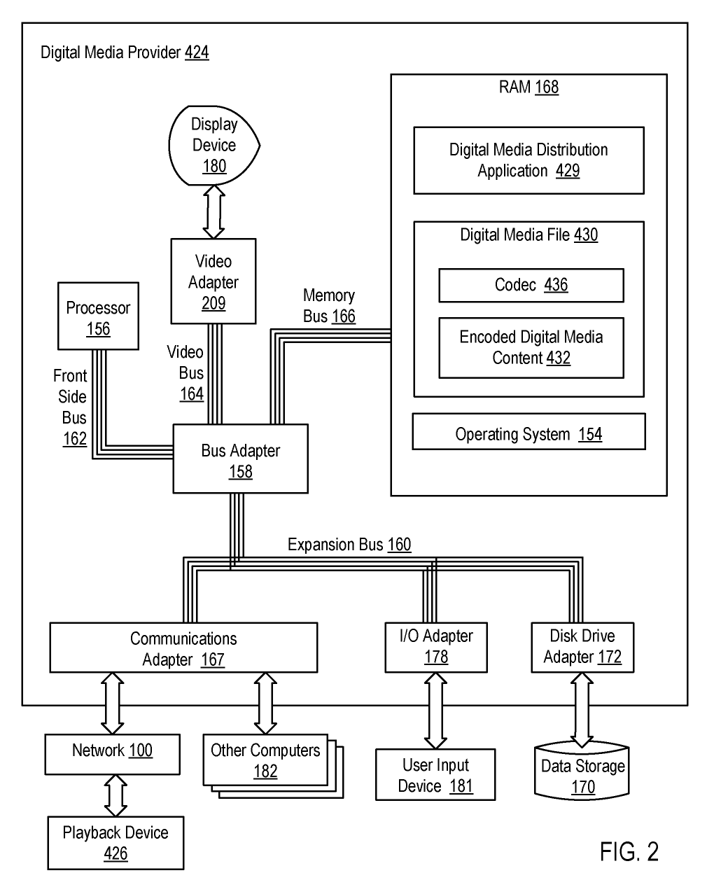

Merging a codec with a digital media file according to embodiments of the present invention is implemented with automated computing machinery, that is, with computers of various kinds. For further explanation, therefore, FIG. 2 sets forth a block diagram of automated computing machinery comprising an example of a computer useful as a digital media provider (424) in merging a codec with a digital media file according to embodiments of the present invention. The digital media provider (424) of FIG. 2 includes at least one computer processor (156) or ‘CPU’ as well as random access memory (168) (‘RAM’) which is connected through a high speed memory bus (166) and bus adapter (158) to processor (156) and to other components of the digital media provider.

Stored in RAM in the example of FIG. 2 is a digital media distribution application (429), a module of computer program instructions that causes the automated computing machinery in the example of FIG. 2 to merge a codec (436) with a digital media file (430) by receiving from a playback device (426) through a data communications network (100) a request for the digital media file (430). The digital media file (430) includes digital media content (432) encoded by the codec (436). The digital media distribution application identifies the codec (436) by which the digital media content (432) was encoded, inserts the codec (436) into the digital media file (430), and distributes (408) the digital media file (430) with the inserted codec (436) to the playback device (426) through the data communications network (100).

Also stored in RAM, in the example of FIG. 2, is an operating system (154). Operating systems useful in digital media providers according to embodiments of the present invention include UNIX™, Linux™, Microsoft NT™, AIX™, IBM's i5/OS™, and others as will occur to those of skill in the art. Operating system (154), digital media distribution application (429), digital media file (430), codec (436), and encoded digital media content (432), in the example of FIG. 2, are shown in RAM (168), but many components of such software typically are stored in non-volatile memory also, for example, on a disk drive (170).

The digital media provider (424) of FIG. 2 includes bus a adapter (158), a computer hardware component that contains drive electronics for the high speed buses, the front side bus (162), the video bus (164), and the memory bus (166), as well as drive electronics for the slower expansion bus (160). Examples of bus adapters useful in digital media providers according to embodiments of the present invention include the Intel Northbridge, the Intel Memory Controller Hub, the Intel Southbridge, and the Intel I/O Controller Hub. Examples of expansion buses useful in digital media providers according to embodiments of the present invention include Industry Standard Architecture (‘ISA’) buses and Peripheral Component Interconnect (‘PCI’) buses.

The digital media provider (424) of FIG. 2 includes disk drive adapter (172) coupled through expansion bus (160) and bus adapter (158) to processor (156) and other components of the digital media provider (424). Disk drive adapter (172) connects non-volatile data storage to the digital media provider (424) in the form of disk drive (170). Disk drive adapters useful in digital media providers include Integrated Drive Electronics (‘IDE’) adapters, Small Computer System Interface (‘SCSI’) adapters, and others as will occur to those of skill in the art. In addition, non-volatile computer memory may be implemented for a digital media provider as an optical disk drive, electrically erasable programmable read-only memory (so-called ‘EEPROM’ or ‘Flash’ memory), RAM drives, and so on, as will occur to those of skill in the art.

The example digital media provider (424) of FIG. 2 includes one or more input/output (‘I/O’) adapters (178). I/O adapters in digital media providers implement user-oriented input/output through, for example, software drivers and computer hardware for controlling output to display devices such as computer display screens, as well as user input from user input devices (181) such as keyboards and mice. The example digital media provider of FIG. 2 includes a video adapter (209), which is an example of an I/O adapter specially designed for graphic output to a display device (180) such as a display screen or computer monitor. Video adapter (209) is connected to processor (156) through a high speed video bus (164), bus adapter (158), and the front side bus (162), which is also a high speed bus.

The exemplary digital media provider (424) of FIG. 2 includes a communications adapter (167) for data communications with other computers (182) and for data communications with a data communications network (100). Such data communications may be carried out serially through RS-232 connections, through external buses such as a Universal Serial Bus (‘USB’), through data communications data communications networks such as IP data communications networks, and in other ways as will occur to those of skill in the art. Communications adapters implement the hardware level of data communications through which one computer sends data communications to another computer, directly or through a data communications network. Examples of communications adapters useful for merging a codec with a digital media file according to embodiments of the present invention include modems for wired dial-up communications, Ethernet (IEEE 802.3) adapters for wired data communications network communications, and 802.11 adapters for wireless data communications network communications.

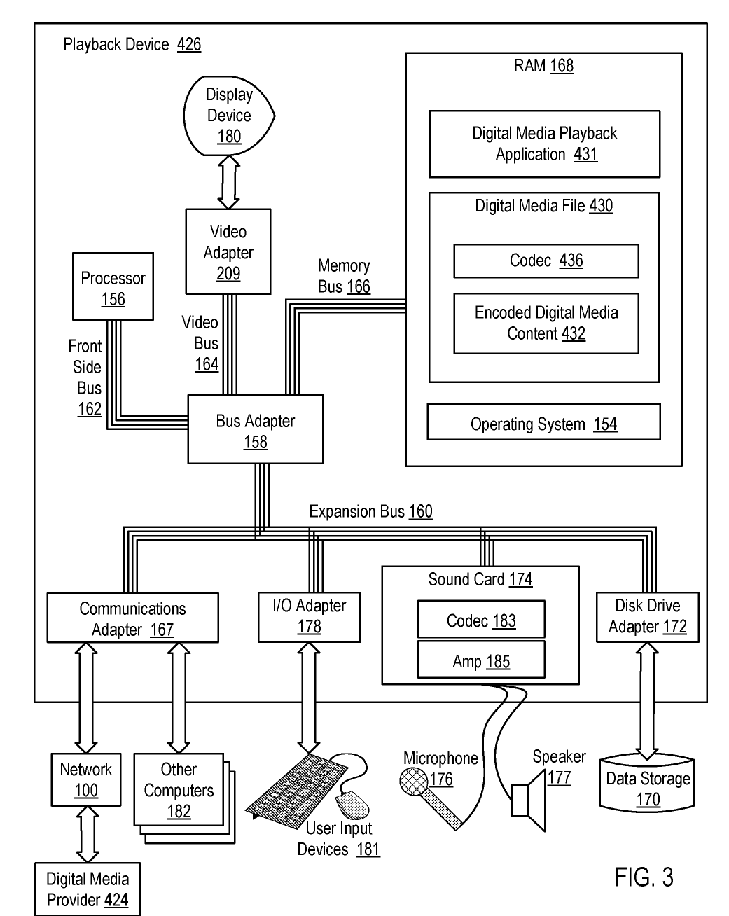

Playing a digital media file according to embodiments of the present invention is generally implemented with a playback device that is, to some extent at least, automated computing machinery, computers. In the system of FIG. 1, for example, all the playback devices (426) are implemented to some extent at least as computers. For further explanation, therefore, FIG. 3 sets forth a block diagram of automated computing machinery comprising an example of a computer useful as a playback device (426) in playing digital media files according to embodiments of the present invention.

The example playback device (426) of FIG. 3 includes several components that are structured and operate similarly as do parallel components of the digital media provider (424), having the same drawing reference numbers, as described above with reference to FIG. 3: at least one computer processor (156), frontside bus (162), RAM (168), high speed memory bus (166), bus adapter (158), video adapter (209), video bus (164), expansion bus (160), communications adapter (167), I/O adapter (178), disk drive adapter (172), an operating system (154), and so on. The example playback device (426) of FIG. 3 also includes a sound card (174), which is an example of an I/O adapter specially designed for accepting input of digital media content, converting the content to audio signals with a codec (183), and outputting the audio through an amplifier (185) a speaker (177). The sound card (174) is connected to processor (156) through expansion bus (160), bus adapter (158), and front side bus (162).

In addition to the operating system (154), also stored in RAM in the example of FIG. 3 is a digital media playback application (431). Depending on the types of digital media files to be played on the playback device, the digital media playback application can be implemented as a wide variety of computer application software, including, for example, a CAD program, a browser, a video game, an MP3 player, and so on. The digital media playback application (431) generally is a module of computer program instructions that, when executed on processor (156), causes the playback device (426) to play a digital media file according to embodiments of the present invention by receiving the digital media file (430) from a digital media provider (424). The digital media file includes digital media content (432) encoded by a codec (436), and the digital media file as received from the digital media provider also includes the codec. The digital media playback application (431) extracts the codec (436) from within the digital media file (430), installs the codec (436) for operation on the playback device (426), and decodes through the codec (436) the digital media content (512) for playback on the playback device (426).

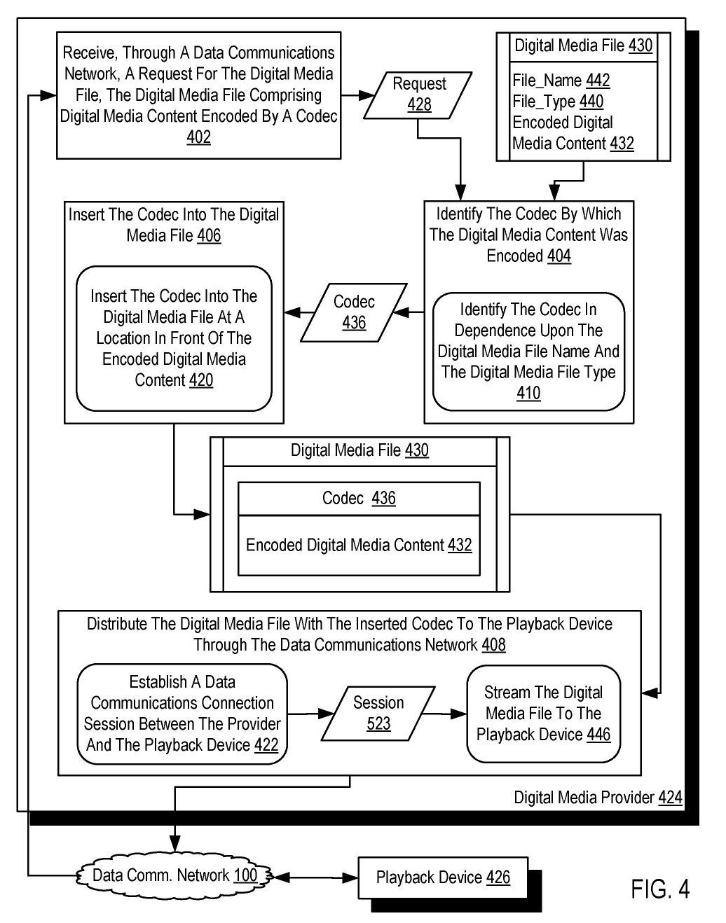

For further explanation, FIG. 4 sets forth a flow chart illustrating an exemplary method for merging a codec with a digital media file according to embodiments of the present invention that includes receiving (402), by a digital media provider (424) a request (428) for the digital media file (430). The digital media file (430) includes digital media content (432) encoded by a codec (436). In this example, the digital media provider receives the request (428) from a playback device (426) through a data communications network (100).

The method of FIG. 4 also includes identifying (404), by the digital media provider (424), the codec (436) by which the digital media content (432) was encoded. The digital media provider is a computer that automatically identifies the codec. The digital media file may contain the identity of the codec, and the digital media provider may identify the codec by reading its identity from the digital media file. The filename extension of the digital media file may identify the codec. For digital media file named myFile.mp3, for example, the digital media provider may identify the MP3 codec as the codec that encoded the digital media in the file. The digital media provider maintains the digital media files that it distributes to playback devices, so the digital media provider may maintain a table of names of digital media files that associates the names of the files with codec and identify the codec that encoded a particular file by a search through the table. Other way of identifying a codec will occur to those of skill in the art, and all such ways are well within the scope of the present invention.

The method of FIG. 4 also includes inserting (406), by the digital media provider (424), the codec (436) into the digital media file (430). Depending on the particular embodiment, the digital media provider may insert the codec at the end of the digital media file, into a header of the digital media file, after the header but before the encoded digital media content in the digital media file, and in other locations within the digital media file as may occur to those of skill in the art.

The method of FIG. 4 also includes distributing (408) the digital media file (430) with the inserted codec (436) to the playback device (426) through a data communications network (100). The digital media provider may distribute the digital media file, for example, by means of TCP/IP, HTTP, WAP, HDTP, PSDN, ISDN, and through other networked data communications methods as well.

In the method of FIG. 4, the digital media file (430) has a digital media file name (442) and a digital media file type (440). The file name may be set forth as information inside the file itself, as shown in the illustrated example (442, 440). Also shown in this example is an alternative of identifying (404) the codec (436) by identifying (410) the codec (436) in dependence upon the digital media file name (442) and the digital media file type (440). That is, the file name and file type may be set forth in the name of the file at the operating system level, as, for example, by the file name myFile.mp3, which identifies a file named myFile.mp3 as having file type MP3.

In the method of FIG. 4, inserting (406) the codec (436) into the digital media file (430) includes inserting (420) the codec (436) into the digital media file (430) at a location in front of the encoded digital media content (432). Inserting (420) the codec (436) in front of the encoded digital media content (432) is an optional alternative procedure which may be preferred, for example, in digital media providers that distribute digital media files by streaming. As mentioned above, however, it is well within the scope of the present invention to insert the codec almost anywhere in the digital media file.

Also in the method of FIG. 4, distributing (408) the digital media file (430) with the inserted codec (436) to the playback device (426) through a data communications network (100) includes establishing (422) a data communications session (523) between the provider (424) and the playback device (426) and streaming (446) the digital media file (430) to the playback device (426). Streaming (446) the digital media file (430) to the playback device (426) through a data communications session is an optional alternative method of distributing the digital media file. Streaming means that the digital media file is delivered to the playback device during playback. Other alternative method of distributing the digital media file include, for example, downloading the entire file, including the codec, to the playback device before beginning playback of the file. For a digital media provider that distributes digital media files by streaming, it may be preferred to insert the codec in the digital media file in front of the digital media content so that the playback device may receive and install the codec before beginning receipt of the digital media content.

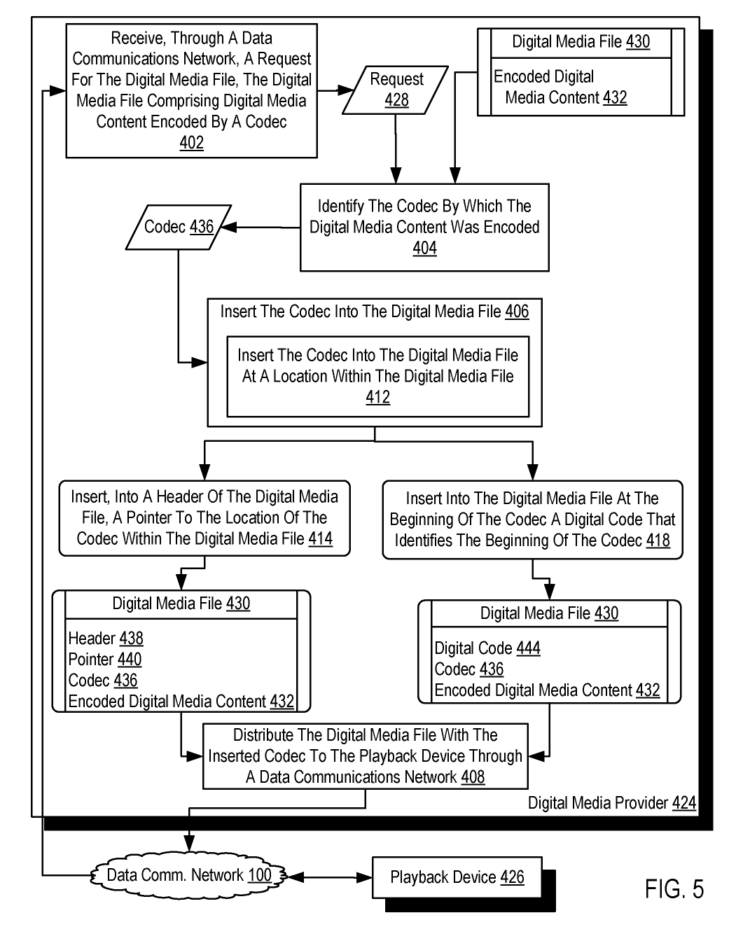

For further explanation, FIG. 5 sets forth a flow chart illustrating a further exemplary method for merging a codec with a digital media file according to embodiments of the present invention. The method of FIG. 5 is similar to the method of FIG. 4, including as it does receiving (402) a request (428) for the digital media file (430), identifying (404) the codec (436) by which the digital media content (432) was encoded, inserting (406) the codec (436) into the digital media file (430), and distributing (408) the digital media file (430) with the inserted codec (436) to the playback device (426) through a data communications network (100).

The example of FIG. 5, however, illustrates two additional, alternative ways of identifying the location of a codec within a digital media file. In a first alternative, after inserting (412) the codec (436) into the digital media file (430) at a location within the digital media file (430), the digital media provider inserts (414), into a header (438) of the digital media file (430), a pointer (440) to the location of the codec (436) within the digital media file (430). The pointer is a data element of the header that contains a location of the codec in the digital media file. In a second alternative method of identifying the location of a codec within a digital media file, after inserting (412) the codec (436) into the digital media file (430) at a location within the digital media file (430), the digital media provider inserts (418) into the digital media file (430) at the beginning of the codec (436) a digital code (444) that identifies the beginning of the codec.

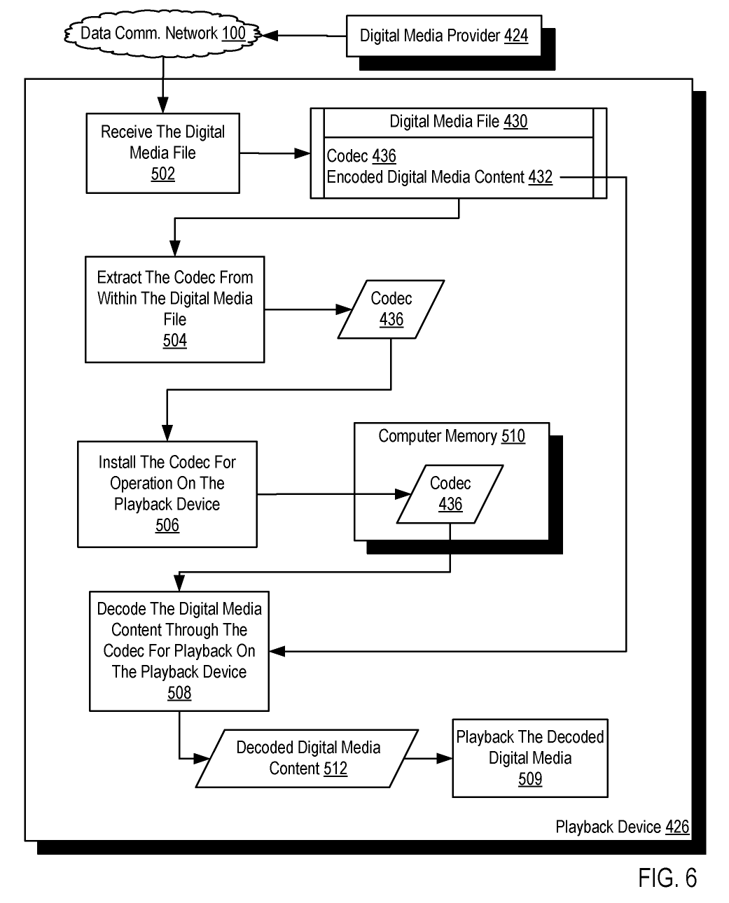

For further explanation, FIG. 6 sets forth a flow chart illustrating an exemplary method for playing a digital media file on a playback device according to embodiments of the present invention. The method of FIG. 6 is implemented on a playback device (426). In the method of FIG. 6, the digital media file includes digital media content (432) encoded by a codec (436), and the digital media file also includes the codec. The digital media file is distributed from a digital media provider (424) to the playback device through a data communications network (100).

The method of FIG. 6 includes receiving (502) the digital media file (430) in the playback device (426). The playback device may receive the digital media file by downloading the entire file before beginning playback of the digital media content of the file, or the playback device may receive the digital media file through a data communications stream, receiving the file during playback of the file.

The method of FIG. 6 includes extracting (504), by the playback device (426), the codec (436) from within the digital media file (430) and installing (506), by the playback device (426), the codec (436) for operation on the playback device (426). The illustrated sequence of extraction and installation with respect to receiving the digital media file is preferred here. The playback device installs the codec before beginning playback. The method of FIG. 6 also includes decoding (508), by the playback device (426) through the codec (436), the digital media content (512) for playback (509) on the playback device (426).

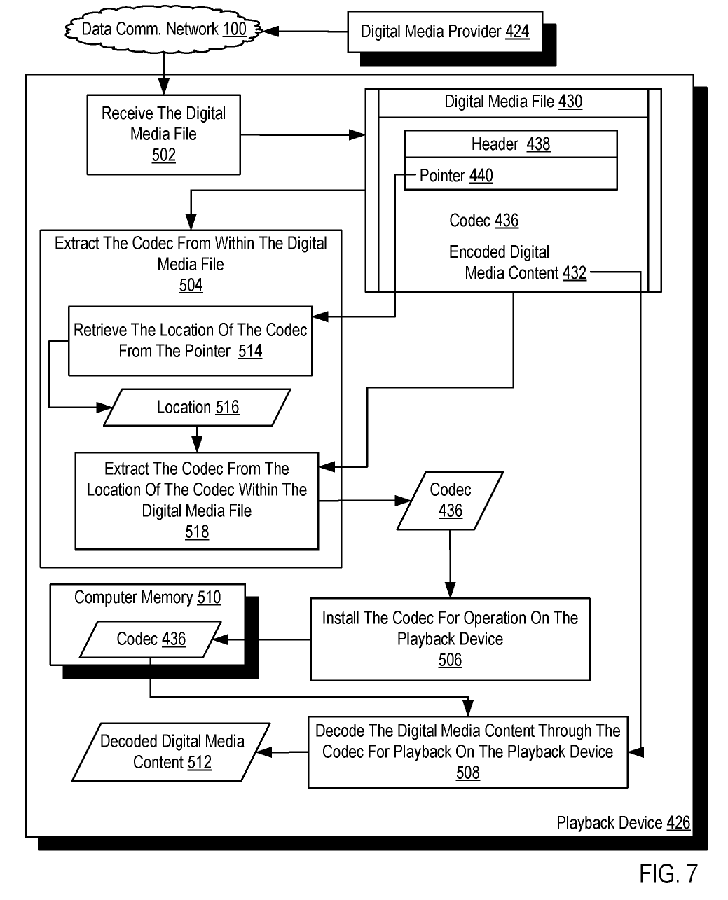

For further explanation, FIG. 7 sets forth a flow chart illustrating a further exemplary method for playing a digital media file on a playback device according to embodiments of the present invention. The method of FIG. 7 is similar to the method of FIG. 6, including as it does receiving (502) the digital media file (430) in the playback device (426), extracting (504) the codec (436) from within the digital media file (430), installing (506) the codec (436) for operation on the playback device (426), and decoding (508) the digital media content (512) for playback on the playback device (426). In the method of FIG. 7, however, the digital media file (430) includes a header (438), and the header includes a pointer (440) to the location (516) of the codec within the digital media file, and extracting (504) the codec (436) from within the digital media file (430) includes retrieving (514) the location (516) of the codec (436) from the pointer (440) and extracting (518) the codec (436) from the location of the codec (436) within the digital media file (430).

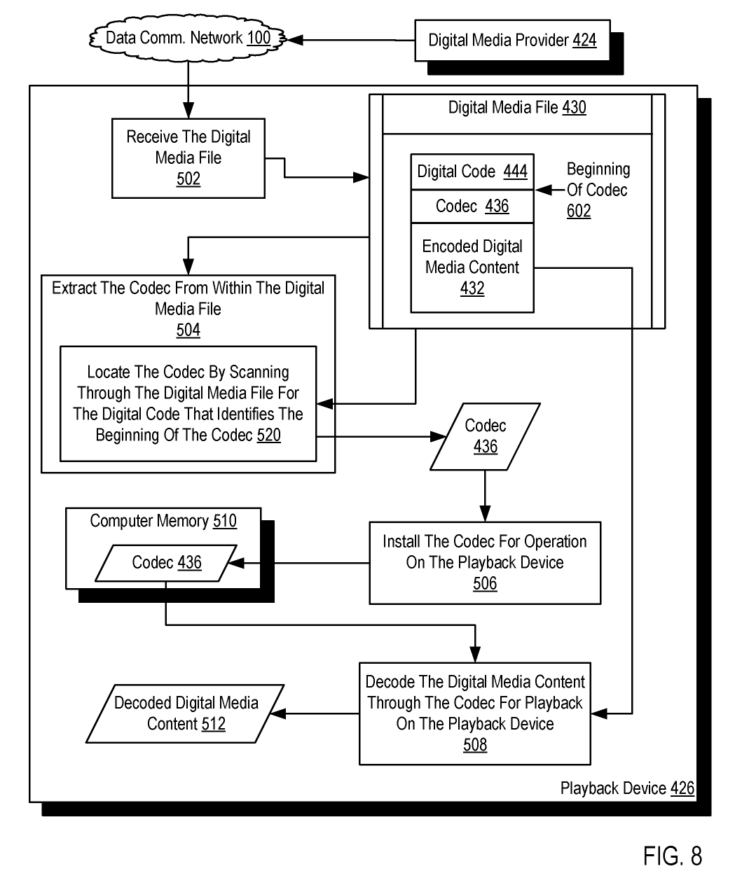

For further explanation, FIG. 8 sets forth a flow chart illustrating a further exemplary method for playing a digital media file on a playback device according to embodiments of the present invention. The method of FIG. 8 is similar to the method of FIG. 6, including as it does receiving (502) the digital media file (430) in the playback device (426), extracting (504) the codec (436) from within the digital media file (430), installing (506) the codec (436) for operation on the playback device (426), and decoding (508) the digital media content (512) for playback on the playback device (426). In the method of FIG. 8, however, the digital media file (430) includes a digital code (444), in the digital media file (430) at the beginning (602) of the codec, that identifies the beginning of the codec, and extracting (504) the codec (436) from within the digital media file (430) includes locating (520) the codec (436) by scanning through the digital media file (430) for the digital code (444) that identifies the beginning of the codec.

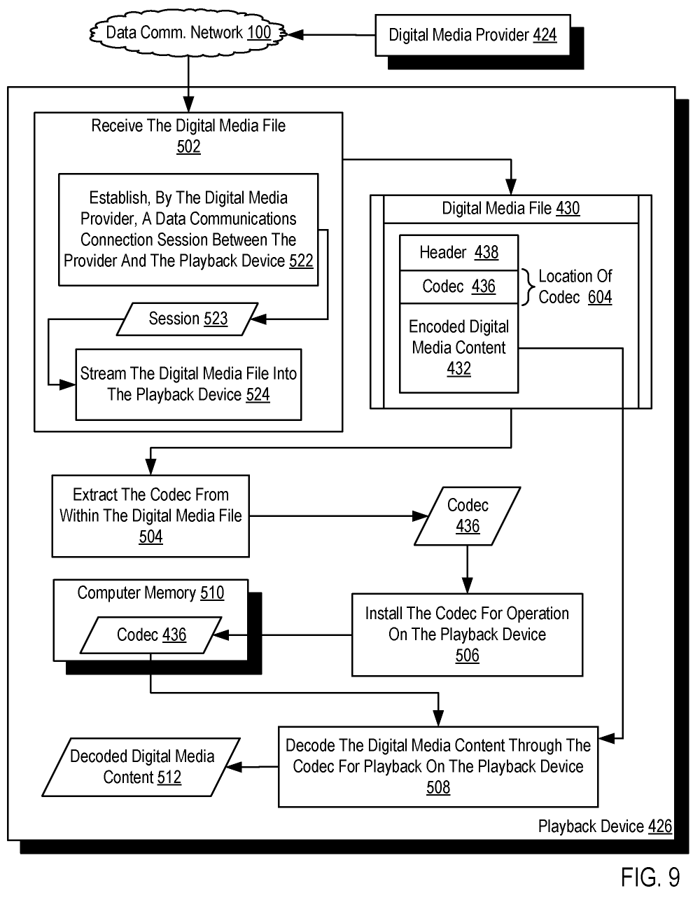

For further explanation, FIG. 9 sets forth a flow chart illustrating a further exemplary method for playing a digital media file on a playback device according to embodiments of the present invention. The method of FIG. 9 is similar to the method of FIG. 6, including as it does receiving (502) the digital media file (430) in the playback device (426), extracting (504) the codec (436) from within the digital media file (430), installing (506) the codec (436) for operation on the playback device (426), and decoding (508) the digital media content (512) for playback on the playback device (426). In the method of FIG. 9, however, the digital media file (430) includes the codec (436) inserted into the digital media file at a location (604) in front of the encoded digital media content (432), and receiving (502) the digital media file (430) in the playback device (426) includes establishing (522), by the digital media provider (424), a data communications session (523) between the provider (424) and the playback device (426) and streaming (524) the digital media file (430) into the playback device (426).

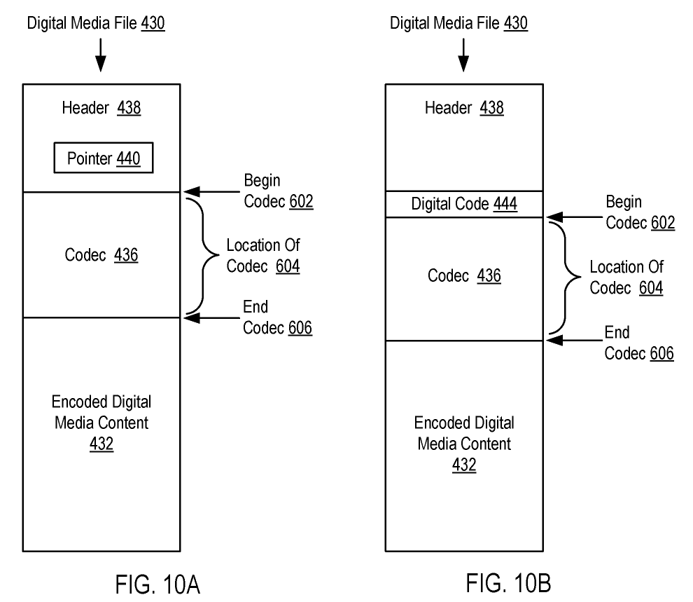

For further explanation, FIG. 10A sets forth a block diagram illustrating an example of a digital media file for use in merging a codec with a digital media file and playing a digital media file on a playback device according to embodiments of the present invention. The example digital media file of FIG. 10A includes digital media content (432) encoded by a codec (436) and also includes the codec (436). That is, the digital media file of FIG. 10A includes both encoded digital media content and the codec by which the digital media content was encoded. In the example of FIG. 10A, the codec (436) is disposed at a location (604) within the digital media file (430). The location (604) of the codec is characterized as a segment of the digital media file marked by the beginning (602) of the codec and the end (606) of the codec. The beginning and end of the codec may be identified as video frame numbers, digital sample numbers, or the like. The digital media file (430) includes a header (438), and the header in turn includes a pointer (440) to the location (604) of the codec (436) within the digital media file (430). By inserting the codec into the digital media file and distributing the digital media file, including the codec, to a playback device, a digital media provider may assure that the playback device always possesses the codec needed to play back the digital media content. With the pointer in the header, the playback device always knows the exact location of the codec in the digital media file.

For further explanation, FIG. 10B sets forth a block diagram of an example digital media file for use in merging a codec with a digital media file and playing a digital media file on a playback device according to embodiments of the present invention. The example digital media file of FIG. 10B includes digital media content (432) encoded by a codec (436) and also includes the codec (436). That is, the digital media file of FIG. 10B includes both encoded digital media content and the codec by which the digital media content was encoded. In the example of FIG. 10B, the codec (436) is disposed at a location (604) within the digital media file (430). The location (604) of the codec is characterized as a segment of the digital media file marked by the beginning (602) of the codec and the end (606) of the codec. The codec (436) in this example is characterized by a digital code (444) at the beginning (602) of the codec (436) that identifies the location (604) of the codec (436) within the digital media file (430). That is, the digital media file (430) includes the digital code (444) inserted in the digital media file at the beginning (602) of the codec. By inserting the codec into the digital media file and distributing the digital media file, including the codec, to a playback device, a digital media provider may assure that the playback device always possesses the codec needed to play back the digital media content. With the digital code in the digital media file marking the location of the codec, the playback device always can find the codec in the digital media file by scanning the file for the digital code. Readers will recognize that by use of pointer like the one in the example of FIG. 10A and digital codes similar to the one in the example of FIG. 10B, the codec can be located almost anywhere in the digital media file, including, for example:
Codec located at the end of the digital media file, with the codec location specified in a pointer in the header or with a single digital code at the beginning of the codec,
Codec located at an arbitrary point anywhere in the encoded digital media content, with the codec location specified by a pointer and codec size field in the header, or with the codec location specified by a beginning and ending codes inserted in the encoded digital content respectively at the beginning and the end of the codec,
Codec located entirely in the header, the codec location specified with beginning and ending codes, no location pointer, and
Codec located after the header but in front of the encoded digital media content, codes for end-header, begin-codec, end-codec, begin-movie—or with a location pointer in the header and a codec size field in the header.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A method of merging a codec with a digital media file, the method comprising:
receiving, by a digital media provider from a playback device through a data communications network, a request for the digital media file, the digital media file comprising digital media content encoded by a codec;
identifying, by the digital media provider, the codec by which the digital media content was encoded;
inserting, by the digital media provider, the codec into the digital media file;
distributing the digital media file with the inserted codec to the playback device through the data communications network.

2. The method of claim 1 wherein:
the digital media file is characterized by a digital media file name and by a digital media file type; and
identifying the codec further comprises identifying the codec in dependence upon the digital media file name and the digital media file type.

3. The method of claim 1 wherein:
inserting the codec into the digital media file further comprises inserting the codec into the digital media file at a location in front of the encoded digital media content; and
distributing the digital media file with the inserted codec to the playback device through a data communications network further comprises establishing a data communications session between the provider and the playback device and streaming the digital media file to the playback device.

4. The method of claim 1 wherein:
inserting the codec further comprises inserting the codec into the digital media file at a location within the digital media file; and
the method further comprises inserting, by the digital media provider into a header of the digital media file, a pointer to the location of the codec within the digital media file.

5. The method of claim 1 wherein:
inserting the codec further comprises inserting the codec into the digital media file at a location within the digital media file; and
the method further comprises inserting into the digital media file at the beginning of the codec a digital code that identifies the beginning of the codec.

6. An apparatus for merging a codec with a digital media file, the apparatus comprising a computer processor and a computer memory operatively coupled to the computer processor, the computer memory having disposed within it computer program instructions capable of:
receiving, by a digital media provider from a playback device through a data communications network, a request for the digital media file, the digital media file comprising digital media content encoded by a codec;
identifying, by the digital media provider, the codec by which the digital media content was encoded;
inserting, by the digital media provider, the codec into the digital media file;
distributing the digital media file with the inserted codec to the playback device through the data communications network.

7. The apparatus of claim 6 wherein:
the digital media file is characterized by a digital media file name and by a digital media file type; and
identifying the codec further comprises identifying the codec in dependence upon the digital media file name and the digital media file type.

8. The apparatus of claim 6 wherein:
inserting the codec into the digital media file further comprises inserting the codec into the digital media file at a location in front of the encoded digital media content; and
distributing the digital media file with the inserted codec to the playback device through a data communications network further comprises establishing a data communications session between the provider and the playback device and streaming the digital media file to the playback device.

9. The apparatus of claim 6 wherein:
inserting the codec further comprises inserting the codec into the digital media file at a location within the digital media file; and
the apparatus further comprises computer program instructions capable of inserting, by the digital media provider into a header of the digital media file, a pointer to the location of the codec within the digital media file.

10. The apparatus of claim 6 wherein:
inserting the codec further comprises inserting the codec into the digital media file at a location within the digital media file; and
the apparatus further comprises computer program instructions capable of inserting into the digital media file at the beginning of the codec a digital code that identifies the beginning of the codec.

11. A method of playing a digital media file on a playback device, the digital media file comprising digital media content encoded by a codec, the digital media file further comprising the codec, the digital media file distributed from a digital media provider to the playback device through a data communications network, the method comprising:
receiving the digital media file in the playback device;
extracting, by the playback device, the codec from within the digital media file;
installing, by the playback device, the codec for operation on the playback device; and
decoding, by the playback device through the codec, the digital media content for playback on the playback device.

12. The method of claim 6 wherein:
the digital media file further comprises a header, the header including a pointer to the location of the codec within the digital media file; and
extracting the codec from within the digital media file further comprises retrieving the location of the codec from the pointer and extracting the codec from the location of the codec within the digital media file.

13. The method of claim 6 wherein:
the digital media file further comprises a digital code, in the digital media file at the beginning of the codec, that identifies the beginning of the codec; and
extracting the codec from within the digital media file further comprises locating the codec by scanning through the digital media file for the digital code that identifies the beginning of the codec.

14. The method of claim 6 wherein:
the digital media file comprises the codec inserted into the digital media file at a location in front of the encoded digital media content; and
receiving the digital media file in the playback device further comprises establishing, by the digital media provider, a data communications session between the provider and the playback device and streaming the digital media file into the playback device.

15. A apparatus for playing a digital media file on a playback device, the digital media file comprising digital media content encoded by a codec, the digital media file further comprising the codec, the digital media file distributed from a digital media provider to the playback device through a data communications network, the apparatus comprising a computer processor and a computer memory operatively coupled to the computer processor, the computer memory having disposed within it computer program instructions capable of:
receiving the digital media file in the playback device;
extracting, by the playback device, the codec from within the digital media file;
installing, by the playback device, the codec for operation on the playback device; and
decoding, by the playback device through the codec, the digital media content for playback on the playback device.

16. The apparatus of claim 15 wherein:
the digital media file further comprises a header, the header including a pointer to the location of the codec within the digital media file; and
extracting the codec from within the digital media file further comprises retrieving the location of the codec from the pointer and extracting the codec from the location of the codec within the digital media file.

17. The apparatus of claim 15 wherein:
the digital media file further comprises a digital code, in the digital media file at the beginning of the codec, that identifies the beginning of the codec; and
extracting the codec from within the digital media file further comprises locating the codec by scanning through the digital media file for the digital code that identifies the beginning of the codec.

18. The apparatus of claim 15 wherein:
the digital media file comprises the codec inserted into the digital media file at a location in front of the encoded digital media content; and
receiving the digital media file in the playback device further comprises establishing, by the digital media provider, a data communications session between the provider and the playback device and streaming the digital media file into the playback device.

19. A digital media file comprising:
digital media content encoded by a codec; and
the codec.

20. The digital media file of claim 10 wherein:
the codec is disposed at a location within the digital media file; and
the digital media file further comprises a header, the header including a pointer to the location of the codec within the digital media file.

21. The digital media file of claim 10 wherein:
the codec is disposed at a location within the digital media file; and
the codec is characterized by a digital code at the beginning of the codec that identifies the location of the codec within the digital media file.
